(19) United States
(12) Patent Application Publication
(10) Pub. No.: US 2026/0077540 A1
(43) Pub. Date: Mar. 19, 2026

(54) MOLD

(71) Applicants: KABUSHIKI KAISHA TOSHIBA, Tokyo (JP); TOSHIBA ELECTRONIC DEVICES & STORAGE CORPORATION, Tokyo (JP)

(72) Inventor: Mineo KOGA, Ibo (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 19/063,475

(22) Filed: Feb. 26, 2025

(30) Foreign Application Priority Data
Sep. 18, 2024 (JP) 2024-161258

(51) Int. Cl. B29C 33/00; H01L 21/56

(52) U.S. Cl. CPC B29C 33/0061; B29C 33/0022; H10W 74/016

(57) ABSTRACT

A mold of an embodiment includes a plunger, a cull, a plurality of cavities, and a plurality of runners. The plunger is provided inside an opening of one of upper and lower dies to be movable forward and backward in the up and down direction. The cull is provided on the other of the upper and lower dies to face the opening. The cavity is capable of receiving a semiconductor chip. The plurality of runners connect the cull to the plurality of cavities. The cull includes a plurality of first flow passages and a plurality of second flow passages. The first flow passage extends from a center toward a connection position with the plurality of runners. The second flow passage extends in a circumferential direction centered on the center. The second flow passage surrounds the plurality of first flow passage. The second flow passage is connected to the plurality of first flow passage.

### CROSS-REFERENCE TO RELATED APPLICATION

This application is based upon and claims the benefit of priority from Japanese Patent Application No. 2024-161258, filed on Sep. 18, 2024; the entire contents of which are incorporated herein by reference.

### FIELD

Embodiments described herein relate generally to a mold.

### BACKGROUND

In semiconductor device manufacturing, a semiconductor chip is sandwiched between a pair of resin sealing molds consisting of heated upper and lower dies and uncured resin is pressed into a cavity of the molds.

In the molds, for example, when a plunger provided on the lower die to be movable forward and backward in the up and down direction rises, a thermosetting resin is pressed against a top of a cull provided on the upper die and is melted. The molten resin is pressed into the cavity capable of receiving the semiconductor chip via the culls, runners, and gates.

The resin melting in the cull has no fixed movement direction. Further, if the plunger is assumed as the center of the resin, the melting rate of the resin at the center of the cull is slower than that at the outside. Furthermore, resin that is not sufficiently melted is prone to trap air. If air is trapped in the resin, the air can affect the ability of the resin to fill the cavity that receives the semiconductor chip, which reduces the resin sealing properties.

### BRIEF DESCRIPTION OF THE DRAWINGS

FIG. 1 is a plan view of a molded product formed using a mold according to an embodiment as viewed from above.

FIG. 2 is a side view of a molded product including a semiconductor chip.

FIG. 3 is an enlarged perspective view of an area around a cull.

FIG. 4 is a cross-sectional view of a mold of a first embodiment corresponding to the cross section B-B of FIG. 3.

FIG. 5 is a bottom view of a cull.

FIG. 6 is a cross-sectional view of the mold of the first embodiment corresponding to the cross section B-B of FIG. 3.

FIG. 7 is a bottom view of the cull.

FIG. 8 is a cross-sectional view of a mold of a second embodiment.

### DETAILED DESCRIPTION

A mold of an embodiment includes a plunger, a cull, a plurality of cavities, and a plurality of runners. The plunger is provided inside an opening of one of upper and lower dies to be movable forward and backward in the up and down direction. The cull is provided on the other of the upper and lower dies to face the opening. The cavity is capable of receiving a semiconductor chip. The plurality of runners connect the cull to the plurality of cavities. The cull includes a plurality of first flow passages and a plurality of second flow passages. The first flow passage extends from a center toward a connection position with the plurality of runners. The second flow passage extends in a circumferential direction centered on the center. The second flow passage surrounds the plurality of first flow passages. The second flow passage is connected to the plurality of first flow passages.

Hereinafter, a mold of an embodiment will be described with reference to the drawings. In the following description, components having the same or similar functions are denoted by the same reference numerals. In addition, duplicate descriptions of those components may be omitted.

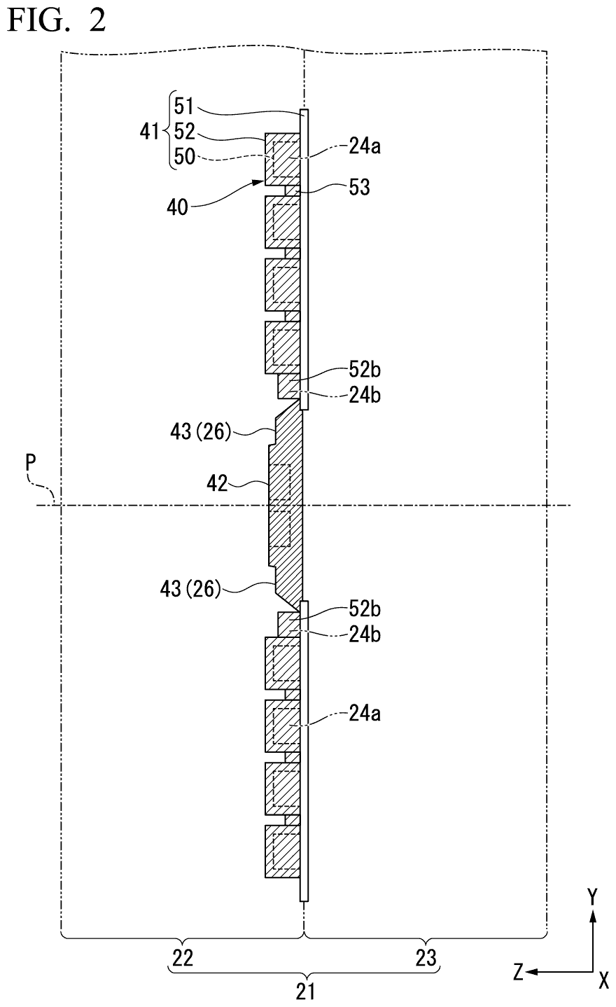

In this specification, in order to indicate the positional relationship of components, etc., the up direction in FIGS. 2 and 4 may be described as “upper”, and the down direction in the drawings may be described as “lower”. In this specification, the concepts of “upper” and “lower” are not necessarily terms that indicate a relationship with the direction of gravity.

The configuration of the mold will be described.

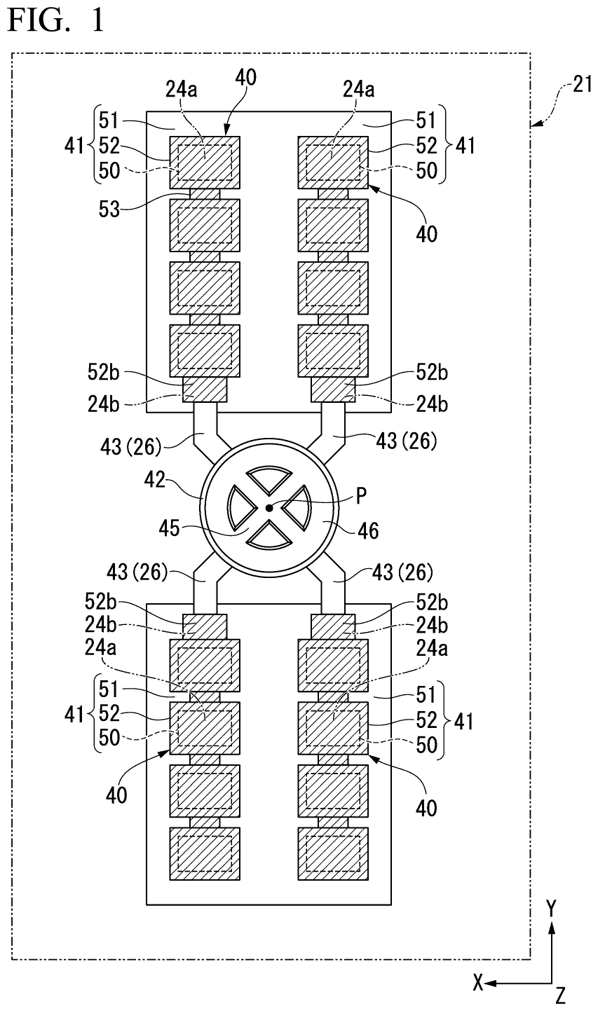

FIG. 1 is a plan view of a molded product including a plurality of semiconductor devices 41 molded as a resin sealing package 40 using a mold 21 of the embodiment as viewed from above. FIG. 2 is a side view of the molded product including the plurality of semiconductor devices 41.

First, the molded product will be described.

The molded product includes the semiconductor device 41, a cull 42, and a runner 43. The semiconductor device 41 includes a semiconductor chip 50, a lead frame 51, and a resin sealing portion 52. The semiconductor chip 50 is mounted on the upper side of a lead frame 51 that is rectangular in plan view. The plurality of semiconductor chips 50 (four in FIG. 1) are mounted on the upper side of the lead frame 51 in a row along the long side direction of the lead frame 51 via connecting portions 53.

In the embodiment, two rows of semiconductor chips 50 are mounted on one lead frame 51 with a gap therebetween in the short side direction of the lead frame 51. Two lead frames 51 on which two rows of semiconductor chips 50 are mounted are arranged in the long side direction of the lead frame 51 with the cull 42 therebetween.

In the following description, the up and down direction perpendicular to the plate surface of the lead frame 51 is referred to as the “Z direction”, the long side direction along the plate surface of the lead frame 51 is referred to as the “Y direction”, and the short side direction along the plate surface of the lead frame 51 is referred to as the “X direction”. In the “Z direction,” the “+Z side” may be referred to as the “upper side” and the “−Z side” as the “lower side.”

Each row including the plurality of semiconductor devices 41 and connecting portions 53 is covered with a molding resin material. The semiconductor chip 50 covered with the resin sealing portion 52 formed of a molding resin material constitutes a part of the resin sealing package 40. In the embodiment, four resin sealing portions 52 are provided in a row. As an example, the resin sealing portion 52 is formed by transfer molding or the like using a thermosetting resin such as a phenolic resin or an epoxy resin.

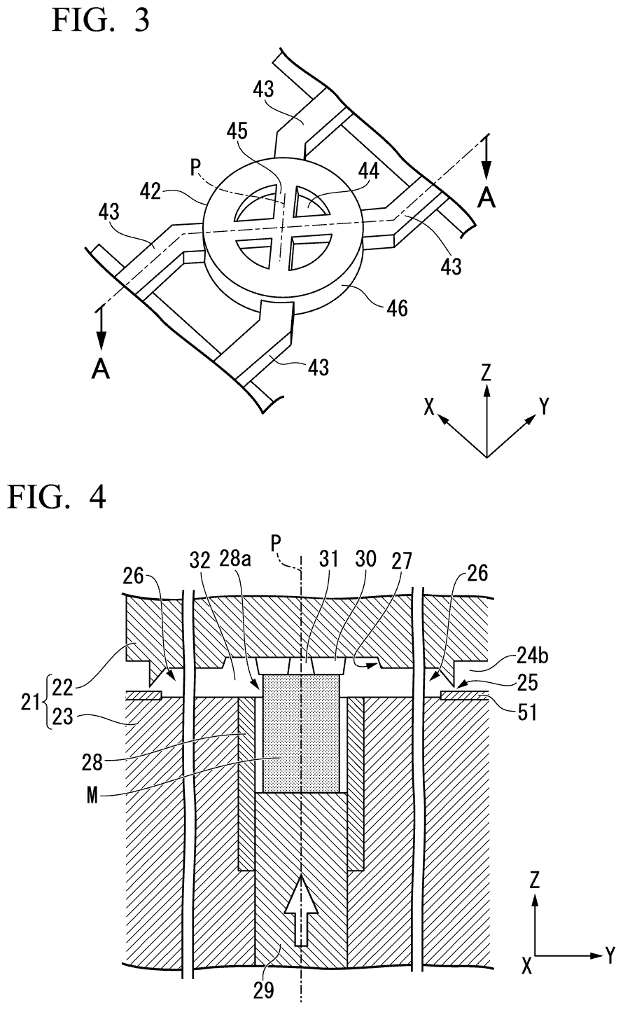

The cull 42 is circular in plan view. The center of the arc of the cull 42 in plan view is called a center P. FIG. 3 is an enlarged perspective view of an area around the cull 42. As shown in FIG. 3, the cull 42 includes a cull recess 44, a first rib 45, and a second rib 46. The cull recess 44 is recessed downward from the upper surface of the cull 42. The maximum depth dimension of the cull recess 44 in the Z direction is equal to or larger than half the maximum thickness dimension of the cull 42 in the Z direction.

The plurality of cull recesses 44 are arranged at intervals in the circumferential direction around the center P (hereinafter, simply referred to as the “circumferential direction”). In this embodiment, four cull recesses 44 are provided. In plan view, the cull recess 44 has a fan shape. The center angles of the cull recesses 44 located on both sides in the X direction with the center P therebetween are the same. The center angles of the cull recesses 44 located on both sides in the Y direction with the center P therebetween are the same.

The facing radii of the cull recesses 44 adjacent to each other in the circumferential direction are parallel to each other with a constant interval therebetween. The first rib 45 extending in the radial direction is formed between the facing radii of the cull recesses 44 adjacent to each other in the circumferential direction. The cull 42 has four cull recesses 44 adjacent to each other in the circumferential direction, and four first ribs 45 are provided at intervals in the circumferential direction. The four first ribs 45 each extend linearly from the center P to the outside in the radial direction (hereinafter, simply referred to as the “radial direction”) centered on the center P.

In the embodiment, since the center angles of the cull recesses 44 located on both sides in the X direction with the center P therebetween are the same and the center angles of the cull recesses 44 located on both side in the Y direction with the center P therebetween are the same, the two first ribs 45 located on both sides of the center P are arranged on the same line and have the same width. That is, the cull 42 includes two ribs that extend radially through the center P and intersect each other. Hereinafter, the rib formed by the two first ribs 45 located on both sides of the center P may be collectively referred to as the first rib 45. The first rib 45 has a tapered shape whose width tapers from the lower side to the upper side.

The second rib 46 has an annular shape that extends in the circumferential direction. The second rib 46 surrounds the plurality of first ribs 45. The second rib 46 is connected to the plurality of first ribs 45 from the outside in the radial direction. The second rib 46 has a tapered shape whose width tapers from the lower side to the upper side. The maximum width dimension of the first rib 45 is equal to or smaller than the maximum width dimension (maximum width dimension in the radial direction) of the second rib 46.

The runners 43 connect the culls 42 to the plurality of (four) resin sealing portions 52. Four runners 43 are provided to correspond to the four resin sealing portions 52 that form a row. The runner 43 is connected perpendicularly to the outer peripheral surface of the cull 42 and the side surface of the resin sealing portion 52. When the runner 43 is connected at an angle from the direction perpendicular to the outer peripheral surface of the cull 42 and the side surface of the resin sealing portion 52, an edge may be formed at the intersection of the portion of the mold 21 where the runner 43 is molded or the portion of the mold where the cull 42 or the resin sealing portion 52 is molded, and this may be damaged during molding or when the mold 21 is operated for maintenance or other purposes. Since the runner 43 is connected perpendicularly to the outer peripheral surface of the cull 42 and the side surface of the resin sealing portion 52, damage to the mold 21 can be suppressed. Further, since the runner 43 is connected perpendicularly to the outer peripheral surface of the cull 42 and the side surface of the resin sealing portion 52, the resin can flow smoothly into the resin sealing portion 52 without being hindered.

### FIRST EMBODIMENT OF MOLD

Next, a first embodiment of the mold 21 will be described.

FIG. 4 is a cross-sectional view of the mold 21 corresponding to the cross section A-A around the cull 42 shown in FIG. 3.

As shown in FIG. 4, the mold 21 includes an upper die 22 and a lower die 23. As shown in FIGS. 1, 2, and 4, a plurality of cavities 24a, 24b and a runner 26 are formed in the mold 21 when the upper die 22 and the lower die 23 are clamped together.

Furthermore, the runner 26 and a cull 27 to be described later are flow passages (spaces) through which a molding resin material flows in the mold 21. The cull 42 described above is a molded product formed by molding a molding resin material with the cull 27. The runner 43 described above is a molded product formed by molding a molding resin material with the runner 26.

The plurality of cavities 24a are spaces or recesses in which the resin sealing packages 40 are molded. The adjacent cavities 24a are connected via the runner. Each of the plurality of cavities 24b is a space or a recess that is connected to the runner 26. The cavities 24a are arranged downstream of the cavities 24b in the flow direction of the molding resin material. The cavity 24b is a flow rate adjusting cavity in which the semiconductor chip 50 is not disposed, in order to adjust the flow rate of the molding resin material flowing into the cavity 24a.

In this embodiment, the width dimension of the cavity 24b in the X direction and the width dimension in the Z direction are, for example, larger than those of the runner 26 and smaller than those of the cavity 24a. Furthermore, since the width dimension in the X direction and the width dimension in the Z direction of the flow rate adjusting cavity 24b are appropriately set according to the size of the product (semiconductor chip 50) in reality, the above dimensional relationship may be different. For example, the width dimension of the runner 26 may be tapered toward the cavity 24b.

When the width dimension in the X direction and the width dimension in the Z direction of the cavity 24b are smaller than, for example, those of the runner 26, the filling pressure of the molding resin material into the cavity 24a located downstream of the cavity 24b is insufficient, and in particular, when the plurality of cavities 24a located downstream of the cavity 24b are disposed, there is a possibility that the cavity 24a will not be filled. Further, if the cavity 24a is not filled, there is a possibility that the resin sealing package 40 will be damaged when the runner 43 and the resin sealing package 40 are separated.

Therefore, in this embodiment, when the flow rate adjusting cavity 24b whose width dimensions in the X direction and the Z direction are larger than those of the runner 26 is provided, it is possible to prevent the cavity 24a from being left unfilled and prevent damage to the resin sealing package 40.

The lower die 23 includes a pot 28 and a plunger 29. The pot 28 has a cylindrical shape centered on the center P. The upper end of the pot 28 is flush with the upper surface of the lower die 23. The pot 28 has an opening 28a facing upward. The plunger 29 is provided to be movable forward and backward in the up and down direction with a small gap provided between the plunger and the inner peripheral wall of the pot 28.

The upper die 22 includes the cull 27. The cull 27 faces the opening 28a in the up and down direction. The cull 27 is a region in which the cull 42 is molded. The cull 27 is recessed upward from the lower surface facing the opening 28a. The cull 27 is recessed from the lower surface into a truncated cone shape centered on the center P.

The runner 26 is connected to each of the cavities 24b and 24a in sequence via a gate 25 when the upper die 22 and the lower die 23 are clamped. In the cavity 24b, a flow rate adjusting portion 52b is molded. In the cavity 24a, the resin sealing portion 52 is molded. The number of cavities 24b is an even number, i.e., four, corresponding to the even number of resin sealing portions 52. The runner 26 is a region in which the runner 43 is molded.

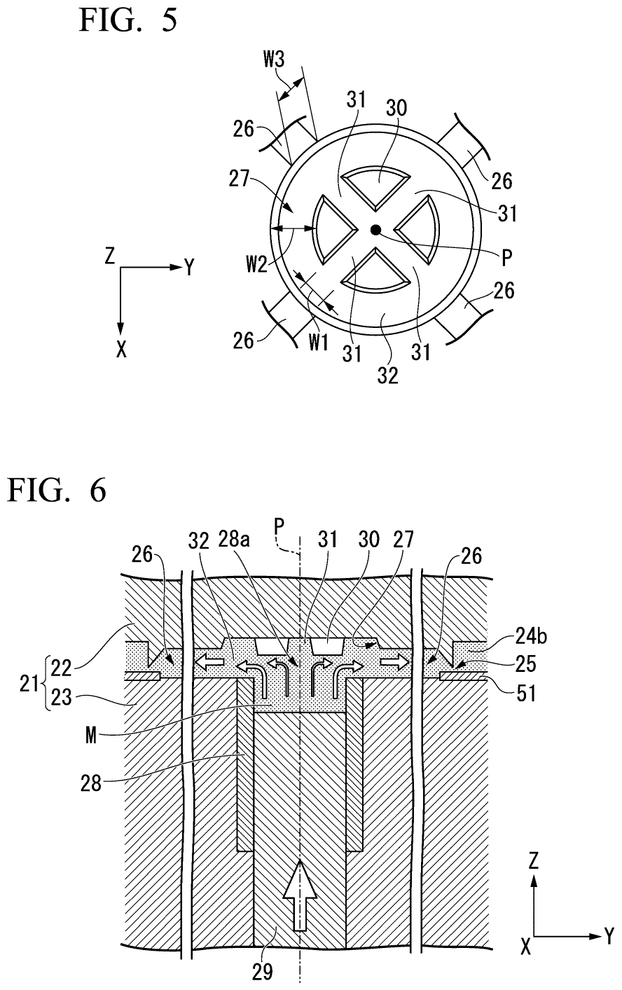

FIG. 5 is a bottom view of the cull 27. As shown in FIG. 5, four runners 26 are provided to correspond to four runners 43. The runner 26 is perpendicularly connected to each of the outer peripheral surface of the cull 27 and the cavity 24b. When the runner 26 is connected at an angle from the direction perpendicular to the outer peripheral surface of the cull 27 and the cavity 24b, as described above, an edge may be formed at the intersection of the outer peripheral surface of the cull 27 or the cavity 24b, and this may be damaged during molding or when the mold 21 is operated for maintenance or other purposes. Since the runner 26 is connected perpendicularly to the outer peripheral surface of the cull 27 and the cavity 24b, damage to the mold 21 can be suppressed. Further, since the runner 26 is connected perpendicularly to the outer peripheral surface of the cull 27 and the cavity 24b, the resin can flow smoothly into the cavity 24b without being hindered.

The cull 27 includes a protrusion 30, a first flow passage 31, and a second flow passage 32. The protrusion 30 is a region in which the cull recess 44 is molded. The protrusion 30 protrudes from the bottom of the cull 27 toward the opening. The plurality of protrusions 30 are provided at intervals in the circumferential direction. The cull 27 of the embodiment includes four protrusions 30. In plan view, the protrusion 30 has a fan shape. The center angles of the protrusions 30 located on both sides in the X direction with the center P therebetween are the same. The center angles of the protrusions 30 located on both sides in the Y direction with the center P therebetween are the same.

The facing radii of the protrusions 30 adjacent to each other in the circumferential direction are parallel to each other with a constant interval therebetween. The first flow passage 31 extending in the radial direction is formed between the facing radii of the protrusions 30 adjacent to each other in the circumferential direction. The cull 27 has four protrusions 30 adjacent to each other in the circumferential direction, and four first flow passages 31 are provided at intervals in the circumferential direction. The four first flow passages 31 each extend linearly from the center P outward in the radial direction.

In the embodiment, since the center angles of the protrusions 30 located on both sides in the X direction with the center P therebetween are the same and the center angles of the protrusions 30 located on both sides in the Y direction with the center P therebetween are the same, the two first flow passages 31 located on both sides of the center P are configured to form a single flow passage having the same width and arranged on the same line. Therefore, the first flow passages 31 are provided in an even number, that is, four, and two of them are arranged on the same line.

As a result, the cull 27 appears to have two flow passages that cross each other and each pass radially through the truncated cone-shaped protrusion 30. Hereinafter, the flow passage formed by the two first flow passages 31 located on both sides of the center P may be collectively referred to as the first flow passage 31.

The first flow passage 31 has a tapered shape in which the width tapers from the upper side to the lower side. Since the first flow passage 31 has a tapered shape, the surface area is larger than in a case where the first flow passage 31 is not tapered, and the heat receiving area increases. Therefore, the viscosity of the molding resin material M that has flowed through the first flow passage 31 decreases, and the flow rate increases.

The depth from the tip of the protrusion 30 to the bottom of the first flow passage 31 is preferably half or more of the maximum depth of the cull 27. Since the depth of the first flow passage 31 is half or more of the maximum depth of the cull 27, the fluidity of the resin material in the first flow passage 31 can be sufficiently ensured. The depth of the first flow passage 31 is preferably 1 mm or more.

The second flow passage 32 has an annular shape that extends along the cull 27 in the circumferential direction. The second flow passage 32 is formed between the outer periphery of the cull 27 and the arc of the protrusion 30 in plan view. That is, the second flow passage 32 surrounds four first flow passages 31. The second flow passage 32 is connected to four first flow passages 31. That is, the protrusion 30 partitions the first flow passage 31 and the second flow passage 32 in the cull 27.

The second flow passage 32 has a tapered shape in which the width tapers from the upper side to the lower side. Since the second flow passage 32 has a tapered shape, the surface area and the heat receiving area increase compared to a case where the second flow passage 32 is not tapered. Therefore, the viscosity of the molding resin material M flowing through the second flow passage 32 decreases, and the flow rate increases.

The depth from the tip of the protrusion 30 to the bottom of the second flow passage 32 is preferably half or more of the maximum depth of the cull 27. Since the depth of the second flow passage 32 is half or more of the maximum depth of the cull 27, the fluidity of the resin material in the second flow passage 32 can be sufficiently ensured. The depth of the second flow passage 32 is the same as the depth of the first flow passage 31. Since the depth of the second flow passage 32 is the same as the depth of the first flow passage 31, the resin material can flow smoothly from the first flow passage 31 to the second flow passage 32.

When viewed in the up and down direction, the first flow passage 31 extends with a constant maximum width dimension W1. The maximum width dimension W1 of the first flow passage 31 is equal to or smaller than the width dimension W2 of the second flow passage 32. When viewed in the up and direction, the maximum width dimension W1 of the first flow passage 31 is equal to or smaller than the width dimension W3 of a connection position 26a between the cull 27 and the runner 26.

In the mold 21 with the above configuration, the lead frame 51 carrying the semiconductor chip 50 is first received at the time of molding. The mold 21 is heated to a predetermined temperature (for example, 180 to 190° C.). When the lead frame 51 carrying the semiconductor chip 50 is received, the tablet-shaped molding resin material M that has been preheated to a predetermined temperature is poured from a resin inlet (not shown) into the pot 28 as shown in FIG. 4 to be in a molten state with the upper die 22 and the lower die 23 clamped together.

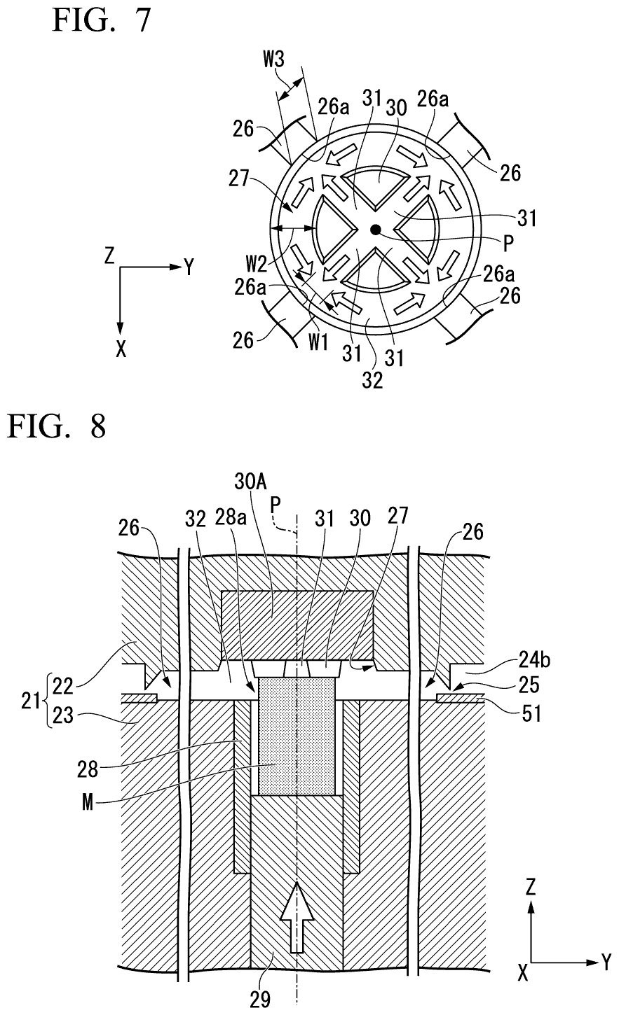

Thereafter, the plunger 29 is advanced toward the upper die 22 by driving a transfer mechanism, and the molten molding resin material M is extruded from the pot 28 with a predetermined pressure as shown in FIG. 6. The molding resin material M extruded from the pot 28 is distributed to the first flow passage 31 and the second flow passage 32 in the cull 27. The molding resin material M distributed to the first flow passage 31 and the second flow passage 32 each flows toward the connection position 26a between the cull 27 and the runner 26 as shown by the white arrows in FIG. 7.

The molding resin material M distributed to the first flow passage 31 flows from the center P toward the connection position 26a between the cull 27 and the runner 26, and then flows into the runner 26 from the joining position of the first flow passage 31 and the second flow passage 32 in the shortest distance. The molding resin material M that has flowed into the runner 26 flows from the gate 25 into the inside of the cavity 24b and the cavity 24a.

On the other hand, the molding resin material M distributed to the second flow passage 32 has a width dimension W2 that is equal to or larger than the maximum width dimension W1 of the first flow passage 31, and therefore has a large surface area and a large heat receiving area. Therefore, the resin viscosity decreases and the molding resin material M flows toward the joining position with the first flow passage 31 at a high flow rate. Therefore, even if the flow length of the molding resin material M that has flowed through the second flow passage 32 is longer than that of the first flow passage 31, the molding resin material M that has flowed through the second flow passage 32 reaches the joining position with the first flow passage 31 at almost the same time as the molding resin material M that has flowed through the first flow passage 31.

Since the maximum width dimension W1 of the first flow passage 31 is equal to or smaller than the width dimension W3 of the connection position 26a between the cull 27 and the runner 26, the amount of molding resin material M that has flowed through the first flow passage 31 is not sufficient to fill the runner 26. On the other hand, since the molding resin material M that has flowed through the second flow passage 32 reaches the joining position of the first flow passage 31 and the second flow passage 32, the molding resin material M that has flowed through the second flow passage 32 compensates for the amount of resin of the molding resin material M that has flowed through the first flow passage 31 and flows into the runner 26 from the joining position.

For example, when the maximum width dimension W1 of the first flow passage 31 is larger than the width dimension W2 of the second flow passage 32, the molding resin material M that has flowed through the second flow passage 32 may not be able to sufficiently join with the molding resin material M that has flowed through the first flow passage 31 and may accumulate in the second flow passage 32. Since the accumulated molding resin material M may be cured slowly, the cull 42 may be left unfilled.

When the cull 42 is unfilled, there may be problems with the operation of adsorbing and discharging the cull 42 using a gate break device in a later process in which a gate portion of a molded product including the resin sealing package 40 is broken to remove unnecessary resin including the cull 42 and runner 43.

In the embodiment, since the molding resin material M that has flowed through the second flow passage 32 does not accumulate, but supplements the amount of molding resin material M that has flowed through the first flow passage 31, and flows into the runner 26 from the joining position, the occurrence of the above problems can be suppressed.

When the molding resin material M is filled from the runner 26 into the cavity 24a via the gate 25 and the cavity 24b, a pressure holding state is maintained for a predetermined period of time for the molding resin material M at a predetermined pressure. Thereafter, the pressure holding state is released, and the plunger 29 is moved backward to open the mold 21. Next, the molded product including the resin sealing package 40 is released from the opened mold 21 and transported to a gate break device that removes unnecessary resin from the molded product, where the gate portion is broken to remove the unnecessary resin including the cull 42 and the runner 43.

According to at least one of the above-described embodiments, since the plurality of first flow passages 31 extending from the center P toward the connection position 26a with the plurality of runners 26 and the second flow passage 32 extending in the circumferential direction, surrounding the plurality of first flow passages 31, and connected to the first flow passages 31 are provided, the molding resin material M can flow into the runner 26 from the joining position of the first flow passage 31 and the second flow passage 32 in the shortest distance from the center P.

Further, according to at least one of the above-described embodiments, since the first flow passage 31 and the second flow passage 32 are formed by the partitioning of the plurality of protrusions 30, the surface area of the first flow passage 31 and the second flow passage 32 increases and the heat receiving area increases. Thus, according to at least one of the above-described embodiments, the viscosity of the molding resin material M flowing through the first flow passage 31 and the second flow passage 32 decreases, so that the flow rate increases, and the resin fluidity can be improved.

Further, for example, if the width dimension of the first flow passage 31 changes, this can cause noise in the resin flow. According to at least one of the above-described embodiments, since the first flow passage 31 extends with a constant maximum width dimension, noise due to the resin flow can be suppressed, and the resin fluidity can be further improved.

Further, according to at least one of the above-described embodiments, since the first flow passages 31 are arranged in pairs on the same line, the direction of the pressure applied to the molding resin material M located at one of the first flow passages 31 from the molding resin material M located at the other thereof is the direction toward the connection position 26a with the runner 26. As a result, according to at least one of the above-described embodiments, the molding resin material M can flow from the first flow passage 31 into the runner 26 in a shorter time.

Further, according to at least one of the above-described embodiments, since the width of each of the first flow passage 31 and the second flow passage 32 is tapered toward the bottom, the surface area is larger than in a case where the width is not tapered, and the heat receiving area increases. Therefore, according to at least one of the above-described embodiments, since the viscosity of the molding resin material M flowing through the first flow passage 31 and the second flow passage 32 is reduced, it is possible to further increase the flow rate.

### SECOND EMBODIMENT OF MOLD

Next, a second embodiment of the mold 21 will be described with reference to FIG. 8.

In this figure, the same components as those in the first embodiment shown in FIGS. 1 to 7 are denoted by the same reference numerals, and the description thereof will be omitted.

FIG. 8 is a partially cross-sectional view showing the mold 21 of the second embodiment.

As shown in FIG. 8, the upper die 22 includes an insert 30A. The insert 30A has a columnar shape. The insert 30A includes a protrusion 30 on the side facing the lower die 23. The insert 30A is detachably provided in a recess 22A formed in the upper die 22.

The recess 22A is open on the side facing the lower die 23. The recess 22A is formed, for example, in a circular shape as viewed from below with the inner peripheral surface being the radial position where the diameter is smallest on the inner peripheral surface of the cull 27 tapered upward. The recess 22A may have a bottom or may penetrate the upper die 22 in the up and down direction.

The other configurations are similar to those of the first embodiment.

In the mold 21 with the above configuration, the insert 30A can be attached and detached through an opening on the side of the upper die 22 facing the lower die 23. The insert 30A is provided replaceably with respect to the upper die 22. In the above first embodiment, since the protrusion 30 is formed in the upper die 22, it is necessary to prepare a new upper die 22 when the number, position (inclination), and maximum width dimension of the first flow passages 31 and the maximum width dimension and the like of the second flow passages 32 are newly set according to the number of the resin sealing packages 40 and runners 43 and their positions in the mold 21.

Further, even if the resin sealing packages 40 are different but the protrusions 30 are the same, it becomes necessary to form the protrusion 30 on a new upper die 22. On the other hand, since it is sufficient to form the recess 22A in the upper die 22 instead of the protrusion 30 even if the protrusion 30 with a new shape is required, the manufacturing efficiency of the upper die 22 is improved. Furthermore, since it is possible to use the insert 30A which is manufactured already or to newly manufacture only the insert 30A when the resin sealing packages 40 are different but the protrusions 30 are the same, the manufacturing efficiency of the resin sealing packages 40 is improved. Furthermore, maintenance of the mold 21 can be performed by simply replacing the insert 30A.

Therefore, according to at least one of the embodiments, it is possible to contribute to improving the manufacturing efficiency of the upper die 22 and the manufacturing efficiency of the resin sealing package 40 in addition to obtaining the same functions and effects as the first embodiment.

Furthermore, the mold 21 of the embodiment has a configuration in which the upper die 22 has the cull 27 and the lower die 23 has the plunger 29, but is not limited to this configuration. The upper die 22 may have the plunger 29 and the lower die 23 may have the cull 27.

Further, in the above embodiments, although a configuration in which the number of the resin sealing packages 40 and the number of the runners 43 are four has been illustrated, the present invention is not limited to this configuration. The number of resin sealing packages 40 and runners 43 may be two or more. It is preferable that the number of resin sealing packages 40 and runners 43 be an even number from the viewpoint of arranging the two first flow passages 31 on both sides of the center P in the same line.

Further, in the above embodiments, although a configuration in which the first flow passage 31 extends linearly from the center P toward the connection position 26a between the cull 27 and the runner 26 has been illustrated, the present invention is not limited to this configuration. From the viewpoint of arranging the two first flow passages 31 on the same line on both sides of the center P, it is optimal for the center of the first flow passage 31 in the width direction to pass through the center P, but if the widthwise center at the intersection of the two first flow passages 31 located on both sides of the center P is 1 mm or less, the same operation and effect can be obtained as when the two first flow passages 31 are arranged on the same line.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A mold comprising:
a plunger which is provided inside one of openings of upper and lower dies to be movable forward and backward in an up and down direction;
a cull which is provided on the other of the upper and lower dies to face the opening;
a plurality of cavities which are capable of receiving a semiconductor chip; and
a plurality of runners which connect the cull to the plurality of cavities,
wherein the cull includes a plurality of first flow passages which extend from a center toward a connection position with the plurality of runners and a second flow passage which extends in a circumferential direction centered on the center, surrounds the plurality of first flow passages, and is connected to the plurality of first flow passages.

2. The mold according to claim 1,
wherein the cavities and the runners are each provided in even numbers, and
wherein the plurality of first flow passages are arranged in pairs on the same line.

3. The mold according to claim 2,
wherein the cull has a plurality of protrusions which protrude from a bottom toward the opening, partition the first flow passage and the second flow passage, and have a fan shape when viewed in the up and down direction.

4. The mold according to claim 3,
wherein a depth from a tip of the protrusion to bottoms of the first flow passage and the second flow passage is half or more of a maximum depth of the cull.

5. The mold according to claim 3,
wherein the other of the upper and lower dies is provided with a detachable insert having the protrusion.

6. The mold according to claim 1,
wherein when viewed in the up and down direction, a maximum width dimension of the first flow passage is equal to or smaller than a width dimension of the connection position.

7. The mold according to claim 6,
wherein when viewed in the up and down direction, the maximum width dimension of the first flow passage is equal to or smaller than a maximum width dimension of the second flow passage.

8. The mold according to claim 6,
wherein the first flow passage extends with the constant maximum width dimension.

9. The mold according to claim 1,
wherein the first flow passage and the second flow passage each have a tapered shape in which the width tapers toward the bottom.
